(19) United States
(12) Patent Application Publication
(10) Pub. No.: US 2026/0093060 A1
(43) Pub. Date: Apr. 2, 2026

(54) MIRROR LAYER AND MIRROR FOR A LITHOGRAPHIC APPARATUS

(71) Applicant: ASML NETHERLANDS B.V., Veldhoven (NL)

(72) Inventors: Silvester HOUWELING, Utrecht (NL); Inci DONMEZ NOYAN, Eindhoven (NL)

(73) Assignee: ASML NETHERLANDS B.V., Veldhoven (NL)

(21) Appl. No.: 19/113,192

(22) PCT Filed: Sep. 29, 2023
(86) PCT No.: PCT/EP2023/077038

§ 371 Date: Mar. 19, 2025

(30) Foreign Application Priority Data
Oct. 14, 2022 (EP) 22201625.5

(51) Int. Cl. G02B 5/08; C23C 14/00; C23C 14/06; C23C 14/34; G03F 7/00

(52) U.S. Cl. CPC G02B 5/0858; C23C 14/0057; C23C 14/0623; C23C 14/0682; C23C 14/3464; G02B 5/0891; G03F 7/7015; G03F 7/702; G03F 7/70233; G03F 7/70316; G03F 7/70958

(57) ABSTRACT

A mirror layer for a lithographic apparatus, the mirror layer including at least one element which forms a chemical bond with silicon having a bond dissociation energy of at least 447 kJ mol⁻¹. Also a method of manufacturing such a mirror layer, a mirror including such a mirror layer, and a lithographic apparatus comprising such a mirror layer or mirror. Also the use of molybdenum silicon sulphide, oxide, selenide, or fluoride in a mirror layer or mirror and the use of such a mirror layer or mirror in a lithographic apparatus or method.

### CROSS-REFERENCE TO RELATED APPLICATIONS

This application claims priority of EP application 22201625.5 which was filed on Oct. 14, 2022 and which is incorporated herein in its entirety by reference.

### FIELD

The present disclosure relates to a mirror layer for a lithographic apparatus, particularly an EUV lithographic apparatus. The present disclosure also relates to a mirror for a lithographic apparatus, a method of controlling diffusion of material in a mirror layer or mirror for lithographic apparatus, a method of manufacturing a mirror layer or mirror for a lithographic apparatus, and the use of such a mirror layer or mirror in a lithographic apparatus or process.

### BACKGROUND

A lithographic apparatus is a machine constructed to apply a desired pattern onto a substrate. A lithographic apparatus can be used, for example, in the manufacture of integrated circuits (ICs). A lithographic apparatus may for example project a pattern from a patterning device (e.g. a mask) onto a layer of radiation-sensitive material (resist) provided on a substrate.

The wavelength of radiation used by a lithographic apparatus to project a pattern onto a substrate determines the minimum size of features which can be formed on that substrate. A lithographic apparatus which uses EUV radiation, being electromagnetic radiation having a wavelength within the range 4-20 nm, may be used to form smaller features on a substrate than a conventional lithographic apparatus (which may for example use electromagnetic radiation with a wavelength of 193 nm).

A lithographic apparatus includes a patterning device (e.g. a mask or reticle). Radiation is provided through or reflected off the patterning device to form an image on a substrate. A membrane assembly, also referred to as a pellicle, may be provided to protect the patterning device from airborne particles and other forms of contamination. Contamination on the surface of the patterning device can cause manufacturing defects on the substrate.

Lithographic apparatuses utilise mirrors to shape and direct radiation within the apparatus from the radiation source to the patterning device, and then on to the substrate. The mirrors need to be very precisely manufactured and also be able to withstand the environment within a lithographic apparatus, which includes being illuminated by intense radiation. Mirrors may be constructed of alternating layers of different materials to provide Bragg reflection. Such alternating layer may for example include alternating silicon and molybdenum layers. Mirrors may be provided with a protective cap to protect underlying layers from the harsh environment within a lithographic apparatus. Existing mirror cap materials may release material, such as silicon, therefrom, which can be referred to as hydrogen-induced outgassing, which can cause contamination within the lithographic apparatus. The contamination can adversely affect the performance of the lithographic apparatus and is therefore undesirable.

It is therefore desirable to provide a mirror which is able to withstand the harsh environment of a lithographic apparatus, in particular an EUV lithography apparatus. It is particularly desirable to provide a mirror which is able to withstand higher powers than previously. It is also desirable to provide a mirror which limits or eliminates contamination of the lithographic apparatus due to release of material from the mirror, which can be referred to as hydrogen-induced outgassing.

The present invention has been devised in an attempt to address at least some of the problems identified above.

### SUMMARY OF THE INVENTION

According to a first aspect of the present disclosure, there is provided a mirror layer comprising at least one element which forms a chemical bond with silicon having a bond dissociation energy of at least 447 kJ mol⁻¹ or at least 4.6 eV.

The selection of materials for a mirror are selected based on criteria such as thermodynamic reduction and oxidation stability, hydride formation, volatalization tendency, heat resistance, amongst others. It has been found that the bond dissociation energy of the materials forming a mirror layer is also an important selection criterion. A mirror layer may be one or more layers included in a mirror comprising a stack of different materials in layers. The mirror layer does not necessary have to contribute to the reflective properties of the mirror and may be included as protection for one or more layers which do contribute to the reflective properties of the mirror. In particular, the presence of bonds in the mirror layer which are stronger than silicon-carbon bonds (which have a bond dissociation energy of around 3.6 eV), means that movement, and ultimately outgassing of material such as silicon from the mirror layer is attenuated. Without wishing to be bound by scientific theory, it is believed that the bonds in the material are less readily released by bond-breaking events and consequently exhibit less and slower diffusion. In other words, the desired bond dissociation energy according to the present disclosure is equal to or greater than the bond dissociation energy of a silicon-carbon bond plus 1 eV, i.e. 3.6 eV+1 eV=4.6 eV, which equates to 447 kJ mol⁻¹ or more.

Elements which are able to form bonds of such strength with silicon include sulphur, oxygen, selenium, and fluorine. In other terms, the minimum bond dissociation energy may be 4.6 eV.

For example, the Si—S bonds in the mirror layer have a higher bond-dissociation energy than Si—N bonds in a similar mirror layer. Whilst oxygen, selenium, and fluorine have higher EUV absorption coefficients than nitrogen or amorphous carbon, the bond dissociation energies of oxygen, selenium and fluorine with silicon are greater than those of nitrogen and amorphous carbon with silicon, so there will be less outgassing of material from the mirror layer. It is envisaged to increase the bond strength such that when EUV light interacts with an EUV mirror then fewer bonds are broken. An increased bond strength may particularly help during plasma exposure, since H ion energies may below 10 eV, whereas the EUV light may be around 92 eV. Such improvement is therefore particularly relevant for degradation by H2 plasma.

The higher bond dissociation energy results in fewer bond breaking events when photons and/or low-energy H ions having energy below or at most 10eV are incident on the mirror layer. This has the consequence that there is less migration of materials, such as silicon through the material to the outer surface of the mirror or mirror layer, which in turn leads to less outgassing of such materials, such as silicon. Sulphur has a lower EUV absorption coefficient as compared to nitrogen and carbon, and also has a higher bond dissociation energy, so the sulphur-carbon bonds are less likely to break in use. Whilst silicon has a lower EUV absorption coefficient than sulphur, it has a lower bond dissociation energy and so is more likely to result in outgassing of silicon. Furthermore, sulphur is not suspected to greatly contribute to the contamination of optics within lithographic apparatuses.

The mirror layer may comprise silicon sulphide. The mirror layer may consist of silicon sulphide. The mirror layer may comprise or consist of one or more of silicon oxide, silicon selenide, or silicon fluoride, or a combination of one or more matrix materials described herein. The mirror layer may include silicon and a metal, a metal silicide, a metal fluoride, a metal boride, a metal carbide, a metal oxide, and/or a metal selenide. The mirror layer may include i) one or more of silicon carbide, germanium carbide, silicon fluoride, germanium fluoride, silicon boride, germanium boride, silicon oxide, and germanium oxide, and ii) a metal. The mirror layer may include i) one or more of a metal, a metal silicide, a metal fluoride, a metal boride, a metal carbide, a metal oxide, and/or a metal selenide, and ii) one or more of silicon carbide, germanium carbide, silicon fluoride, germanium fluoride, silicon boride, germanium boride, silicon oxide, and germanium oxide.

The mirror layer may include one or more of a metal carbide, a metal boride, a metal nitride, a metal fluoride, a metal silicide, or a metal. The metal (which may be the metal is any of the aforementioned compounds or elemental metal) may be selected from one or more of molybdenum, zirconium, yttrium, lanthanum, scandium, niobium, iridium, chromium, vanadium, platinum, rhodium, hafnium, and ruthenium. Yttrium oxide, zirconium oxide, hafnium oxide, and carbon nitride show particular potential since they include bonds with bond dissociation energies greater than 4.6 eV. Such materials also have ultimate tensile strengths similar to that of silicon.

The sulphur-containing mirror layer may have a composition of SiS_{2-y}, wherein 0≤y<2. The inclusion of sulphur within the mirror layer is believed to reduce outgassing by bonding the sulphur to the silicon strongly, thereby inhibiting silicon migration and outgassing.

The mirror layer may at least partially have the formula MoₐSi_{b}S_{c}, wherein 0<a≤30, 50≤b≤90, and 0<c≤50, (by mole %). In embodiments, 10≤a≤30, (by mole %). In embodiments, 60≤b≤70, (by mole %). In embodiments, 20≤c≤30, (by mole %). The thermodynamic stability of the mirror layer can depend on the relative amounts of the metal, silicon and sulphur. The amount of sulphur is controlled to avoid the formation of gaseous phases at certain temperatures and to also avoid unwanted oxidation. The amount of silicon is controlled to provide sufficient strength to the mirror layer whilst reducing the likelihood of outgassing of silicon.

The mirror layer may include silicon and metal, preferably molybdenum, and the ratio (by mol %) of Si:Metal (Mo) may deviate from 2.0. In other words, the Si:Metal ratio is lower than the stoichiometric value, namely that there is less than the stoichiometric value of silicon. In this way, the mirror layer is relatively metal rich, which reduces the likelihood of silicon outgassing. This also allows for a thinner layer than would be the case with a stoichiometric amount of silicon to molybdenum.

Throughout the present disclosure, it will be appreciated that unintentional minor contaminants may be present due to manufacturing and materials tolerances. The contaminants may be present in amounts which are inconsequential to the performance of the layer. In such embodiments, additional elements are not intentionally included.

According to a second aspect of the present disclosure, there is provided a mirror comprising a mirror layer according to the first aspect of the present disclosure.

The mirror may be a multi-layered mirror. The mirror may include a stack of layers of different materials. The stack may include alternating layers or silicon and molybdenum.

According to a third aspect of the present disclosure, there is provided a method of manufacturing a mirror layer or mirror according to the first or second aspects of the present disclosure, wherein the method includes sputtering, optionally co-sputtering.

Sputtering, preferably co-sputtering, provides for the exact composition of a mirror layer or mirror to be controlled, thereby allowing the manufacture of a mirror layer or mirror according to the present disclosure.

According to a fourth aspect of the present disclosure, there is provided a lithographic apparatus comprising a mirror layer or mirror according to the first aspect or second aspects, or a mirror layer or mirror manufactured according to the method of the third aspect of the present invention.

According to a fifth aspect of the present disclosure, there is provided the use of molybdenum silicon sulphide, oxide, selenide, or fluoride in a mirror layer or mirror.

The mirror layer or mirror may be the mirror layer or mirror according to any aspect of the present disclosure. In embodiments, the mirror layer or mirror may at least partially have the formula MoₐSi_{b}S_{c}, wherein 0<a≤30, 50≤b≤90, and 0<c≤50, (by mole %).

According to a sixth aspect of the present disclosure, there is provided the use of a mirror layer, mirror, or lithographic apparatus according to the first, second, fourth or fifth aspect of the present disclosure in a lithographic apparatus or method.

It will be appreciated that features described in respect of one embodiment may be combined with any features described in respect of another embodiment and all such combinations are expressly considered and disclosed herein.

### BRIEF DESCRIPTION OF THE DRAWINGS

Embodiments of the invention will now be described, by way of example only, with reference to the accompanying schematic drawing in which corresponding reference symbols indicate corresponding parts, and in which:

FIG. 1 depicts a lithographic apparatus according to an embodiment of the invention; and

FIG. 2 depicts a multi-layered mirror according to one aspect of the present disclosure including a mirror layer according to the present disclosure.

The features and advantages of the present invention will become more apparent from the detailed description set forth below when taken in conjunction with the drawings, in which like reference characters identify corresponding elements throughout. In the drawings, like reference numbers generally indicate identical, functionally similar, and/or structurally similar elements.

### DETAILED DESCRIPTION

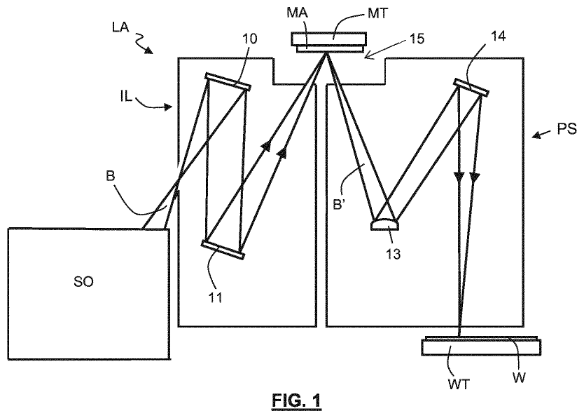

FIG. 1 shows a lithographic system according to the present invention. The lithographic system comprises a radiation source SO and a lithographic apparatus LA. The radiation source SO is configured to generate an extreme ultraviolet (EUV) radiation beam B. The lithographic apparatus LA comprises an illumination system IL, a support structure MT configured to support a patterning device MA (e.g. a mask), a projection system PS and a substrate table WT configured to support a substrate W. The illumination system IL is configured to condition the radiation beam B before it is incident upon the patterning device MA. The projection system is configured to project the radiation beam B (now patterned by the mask MA) onto the substrate W. The substrate W may include previously formed patterns. Where this is the case, the lithographic apparatus aligns the patterned radiation beam B with a pattern previously formed on the substrate W. In this embodiment, a pellicle 15 is depicted in the path of the radiation and protecting the patterning device MA. It will be appreciated that the pellicle 15 may be located in any required position and may be used to protect any of the mirrors in the lithographic apparatus. Any one or more of the mirrors may be a mirror according to the present disclosure.

The radiation source SO, illumination system IL, and projection system PS may all be constructed and arranged such that they can be isolated from the external environment. A gas at a pressure below atmospheric pressure (e.g. hydrogen) may be provided in the radiation source SO. A vacuum may be provided in illumination system IL and/or the projection system PS. A small amount of gas (e.g. hydrogen) at a pressure well below atmospheric pressure may be provided in the illumination system IL and/or the projection system PS.

The radiation source SO shown in FIG. 1 is of a type which may be referred to as a laser produced plasma (LPP) source. A laser, which may for example be a CO₂ laser, is arranged to deposit energy via a laser beam into a fuel, such as tin (Sn) which is provided from a fuel emitter. Although tin is referred to in the following description, any suitable fuel may be used. The fuel may for example be in liquid form, and may for example be a metal or alloy. The fuel emitter may comprise a nozzle configured to direct tin, e.g. in the form of droplets, along a trajectory towards a plasma formation region. The laser beam is incident upon the tin at the plasma formation region. The deposition of laser energy into the tin creates a plasma at the plasma formation region. Radiation, including EUV radiation, is emitted from the plasma during de-excitation and recombination of ions of the plasma.

The EUV radiation is collected and focused by a near normal incidence radiation collector (sometimes referred to more generally as a normal incidence radiation collector). The collector may have a multilayer structure which is arranged to reflect EUV radiation (e.g. EUV radiation having a desired wavelength such as 13.5 nm). The collector may have an elliptical configuration, having two ellipse focal points. A first focal point may be at the plasma formation region, and a second focal point may be at an intermediate focus, as discussed below.

The laser may be separated from the radiation source SO. Where this is the case, the laser beam may be passed from the laser to the radiation source SO with the aid of a beam delivery system (not shown) comprising, for example, suitable directing mirrors and/or a beam expander, and/or other optics. The laser and the radiation source SO may together be considered to be a radiation system.

Radiation that is reflected by the collector forms a radiation beam B. The radiation beam B is focused at a point to form an image of the plasma formation region, which acts as a virtual radiation source for the illumination system IL. The point at which the radiation beam B is focused may be referred to as the intermediate focus. The radiation source SO is arranged such that the intermediate focus is located at or near to an opening in an enclosing structure of the radiation source.

The radiation beam B passes from the radiation source SO into the illumination system IL, which is configured to condition the radiation beam. The illumination system IL may include a facetted field mirror device 10 and a facetted pupil mirror device 11. The faceted field mirror device 10 and faceted pupil mirror device 11 together provide the radiation beam B with a desired cross-sectional shape and a desired angular distribution. The radiation beam B passes from the illumination system IL and is incident upon the patterning device MA held by the support structure MT. The patterning device MA reflects and patterns the radiation beam B. The illumination system IL may include other mirrors or devices in addition to or instead of the faceted field mirror device 10 and faceted pupil mirror device 11.

Following reflection from the patterning device MA the patterned radiation beam B enters the projection system PS. The projection system comprises a plurality of mirrors 13, 14 which are configured to project the radiation beam B onto a substrate W held by the substrate table WT. The projection system PS may apply a reduction factor to the radiation beam, forming an image with features that are smaller than corresponding features on the patterning device MA. A reduction factor of 4 may for example be applied. Although the projection system PS has two mirrors 13, 14 in FIG. 1, the projection system may include any number of mirrors (e.g. six mirrors).

The radiation sources SO shown in FIG. 1 may include components which are not illustrated. For example, a spectral filter may be provided in the radiation source. The spectral filter may be substantially transmissive for EUV radiation but substantially blocking for other wavelengths of radiation such as infrared radiation.

In an embodiment the membrane assembly 15 is a pellicle for the patterning device MA for EUV lithography. The membrane assembly 15 can be used for a dynamic gas lock or for a pellicle or for another purpose. In an embodiment the membrane assembly 15 comprises a membrane formed from at least one membrane layer having an emissivity of 0.3 or more. In order to ensure maximized EUV transmission and minimized impact on imaging performance it is preferred that the membrane is only supported at the border.

If the patterning device MA is left unprotected, the contamination can require the patterning device MA to be cleaned or discarded. Cleaning the patterning device MA interrupts valuable manufacturing time and discarding the patterning device MA is costly. Replacing the patterning device MA also interrupts valuable manufacturing time.

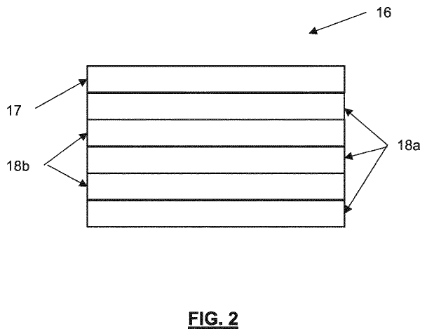

FIG. 2 is a schematic depiction of a multi-layered mirror 16 according to one aspect of the present disclosure including a mirror layer 17 according to the present disclosure. The mirror 16 includes alternating layers of different materials 18a, 18b, which form a Bragg reflector. It will be appreciated that the mirror may include more layers than shown in the schematic depiction and that the relative dimensions of the layers may be otherwise than shown. In the depicted embodiment, mirror layer 17 is a cap layer, but it will be appreciated that the mirror layer may be one or more of the alternating layers of different materials 18a, 18b in other embodiments.

The present invention targets an attenuation of hydrogen-induced outgassing (HIO) of Si-containing species from Metal Silicide-based Composite (MSC) mirrors under EUV scanner operation conditions. In embodiments, the present disclosure describes a mirror layer or mirror in which silicon is bound to a secondary element “ψ”, called the Si-ψ_{y} matrix. A MSC material-selection parameter may be the “bond dissociation energy (BDE)” of Si-ψ bonds in the matrix. The BDE of Si-ψ bonds in the matrix governs the breaking of Si-ψ bonds during scanner operation, which generates free Si species that can diffuse and exit the mirror layer or mirror via HIO processes. A high Si-ψ BDE thus results in attenuated HIO processes. The BDE as a parameter to select mirror layer or mirror materials is described herein.

An aspect of the invention is a new mirror layer or mirror Si-ψ material combination, with ψ=S, O, Se, or F. For instance, in the case of ψ=S, the Si—S_{2-y} matrix material, Si—S bonds in the matrix have a higher bond dissociation energy (BDE) than Si—N in an SiN matrix; as stated a high BDE results in less bond breaking events when photons are incident on the material and may result in a smaller amount of migration of Si through the matrix material to the outer surfaces, which consequently results in less Si outgassing. Based on the BDE of Si—S, as well as other compositions described herein, the mirror layer or mirror of the present disclosure exhibits reduced outgassing compared to other options such as MoSiN, MoSiSi and MoSiC.

A threshold BDE-value is defined here as any value greater than Si—N and Si—C and Si—Si bonds.

Related to the bond dissociation energy (BDE) of element w with Si and the migration and successive outgassing of Si atoms, if the Si-ψ BDE is sufficiently strong then Si migration is inhibited and outgassing can only temporarily occur until the external region of the mirror layer or mirror is depleted of Si. Excessive Si is able to migrate through the mirror layer or mirror and can be released at the external regions in a number of processes denoted as said Si outgassing (such as SiO₂ desorption or SiH₄ formation. The material combinations described herein with potential low levels of outgassing thus exhibits a high Si-ψ bond energy, such that bond dissociation is limited and with that also the migration of atoms of Si through the Siψ₂₋ₓ matrix is limited as well as the outgassing.

A value of at most 1.1·10¹⁵ at.·cm⁻² outgassed Si atoms per 10000 scanner wafers is taken here as an exemplary specification of acceptable HIO amount.

Among the crucial parameters that determine whether a volatile species poses a risk for reducing the optical performance of an EUV mirror is firstly the sticking probability of that species to the surface of the EUV mirror and secondly whether the species oxidizes on the surface of the mirror.

As a minimum, the BDE value the Si—C bond is considered as that is the highest BDE value of the three composite pellicle varieties of MoSiC, MoSiSi and MoSiN, which all exhibit outgassing of Si, which is hypothesized here to be related to atomic migration. As such, the BDE value of the atom bonds are preferably larger to reduce bond breaking events and to thus attenuate consequent atom migration. The present invention claims that for any improvement the BDE must exceed that “SiC+1 eV” value. According to the present invention, by providing a mirror layer or mirror comprising a material that forms a strong bond to silicon, it is possible to reduce silicon outgassing. Strong silicon-sulphur bonds have a higher bond dissociation energy than silicon-nitrogen or silicon-silicon bonds, and so when the mirror is illuminated with EUV light, and/or is subjected to the low-ion energy H2 scanner plasma having H ions with energy below or at most 10 eV, there is a lower likelihood of bond dissociation, which leads to silicon migration and outgassing. Sulphur is not greatly associated with contamination of optics within a lithography apparatus and so does not present a significant contamination concern if some sulphur is outgassed.

The present invention may allow for uncapped mirrors due to the reduced propensity for silicon outgassing.

The mirror according to the present disclosure may be manufactured via sputtering. Sputtering a molybdenum silicide target and a silicon sulphide target results in a mirror layer having metal rich molybdenum silicide crystals in a silicon sulphide matrix. Similarly, reactive sputtering of molybdenum disilicide in a hydrogen sulphide atmosphere results in a mirror of the present disclosure. By providing sulphur in the matrix, the bonds to silicon are strong and silicon outgassing may only be observed until the external region of the mirror is depleted of silicon which is liable to outgas. It is considered that silicon migration is inhibited by the strong bond to sulphur.

As such, the present disclosure provides for mirrors which have similar or better optical performance as compared to other mirrors, but which have lower amounts of silicon outgassing as well as acceptable EUV reflectivity, and also acceptable emissivity, which allows them to operate within lithographic apparatuses, particularly EUV apparatuses.

While specific embodiments of the invention have been described above, it will be appreciated that the invention may be practiced otherwise than as described.

The descriptions above are intended to be illustrative, not limiting. Thus it will be apparent to one skilled in the art that modifications may be made to the invention as described without departing from the scope of the claims set out below.

1. A mirror layer for a lithographic apparatus, the mirror layer comprising at least one element which forms a chemical bond with silicon having a bond dissociation energy of at least 447 kJ mol⁻¹ or at least 4.6 eV.

2. The mirror layer according to claim 1, wherein the at least one element is selected from sulphur, oxygen, selenium, or fluorine.

3. The mirror layer according to claim 1, wherein the mirror layer includes one or more selected from: a metal carbide, a metal boride, a metal nitride, a metal fluoride, a metal silicide, or a metal.

4. The mirror layer according to claim 1, wherein the mirror layer includes silicon and a metal, a metal silicide, a metal fluoride, a metal boride, a metal carbide, a metal oxide, and/or a metal selenide.

5. The mirror layer according to claim 1, wherein the mirror layer includes i) one or more selected from: silicon carbide, germanium carbide, silicon fluoride, germanium fluoride, silicon boride, germanium boride, silicon oxide, and/or germanium oxide, and ii) a metal.

6. The mirror layer according to claim 1, wherein the mirror layer includes i) one or more selected from: a metal, a metal silicide, a metal fluoride, a metal boride, a metal carbide, a metal oxide, and/or a metal selenide, and ii) one or more selected from: silicon carbide, germanium carbide, silicon fluoride, germanium fluoride, silicon boride, germanium boride, silicon oxide, and/or germanium oxide.

7. The mirror layer according to claim 1, wherein the mirror layer has a composition of SiS_{2-y}, wherein 0≤y≤2.

8. The mirror layer according to claim 1, wherein the mirror layer at least partially has the formula MoₐSi_{b}S_{c}, wherein 0<a≤30, 50≤b≤90, and 0<c≤50, (by mole %).

9. The mirror layer according to claim 8, wherein 10≤a≤30, (by mole %).

10. The mirror layer of claim 8, wherein 60≤b≤70, (by mole %).

11. The mirror layer of claim 8, wherein 20≤c≤30, (by mole %).

12. The mirror layer of claim 1, wherein the mirror includes silicon and molybdenum and the ratio (by mole %) of Si:Mo deviates from 2.0.

13. A mirror comprising the mirror layer according to claim 1.

14. The mirror according to claim 13, wherein the mirror is a multi-layered mirror.

15. A method of manufacturing the mirror layer or mirror according to claim 1, wherein the method includes sputtering.

16. A lithographic apparatus comprising the mirror layer according to claim 1.

17. A mirror layer or mirror comprising molybdenum silicon sulphide, oxide, selenide, or fluoride.

18. (canceled)

19. A lithographic apparatus comprising the mirror or mirror layer according to claim 17.

20. The mirror layer of claim 1, wherein the mirror layer comprises silicon sulphide, silicon oxide, silicon selenide, or silicon fluoride.

21. The mirror layer of claim 3, wherein the metal is one or more selected from: molybdenum, zirconium, yttrium, lanthanum, scandium, niobium, iridium, chromium, vanadium, platinum, rhodium, hafnium, and/or ruthenium.
